(19) United States
(12) Patent Application Publication
(10) Pub. No.: US 2003/0189245 A1
(43) Pub. Date: Oct. 9, 2003

(54) Flip chip assembly and method for producing the same

(75) Inventor: Jen Kuang Fang, Shinyuan Hsiang (TW)

Correspondence Address: LOWE HAUPTMAN GILMAN & BERNER, LLP, Suite 310, 1700 Diagonal Road, Alexandria, VA, 22314, US

(73) Assignee: ADVANCED SEMICONDUCTOR ENGINEERING, INC.

(21) Appl. No.: 10/118,002

(22) Filed: Apr. 9, 2002

(51) Int. Cl. H01L 23/10

(52) U.S. Cl. 257/706; 257/707

(57) ABSTRACT

A flip chip assembly comprises an IC chip having a plurality of first solder bumps formed on a lower surface thereof and a heat sink having a plurality of second solder bumps, wherein the heat sink are attached to an upper surface of the IC chip via the second solder bumps. The present invention further provides a method for producing the flip chip assembly.

### BACKGROUND OF THE INVENTION

1. Field of the Invention

This invention relates to a flip chip assembly and a method to make the same, and more specifically to a flip chip assembly having a heat sink and a method to make the same.

2. Description of the Related Art

As is well known, there is a trend to reduce the size of semiconductor devices and integrated circuits while having the devices and circuits perform more functions. As a result of the increased functionality, such devices and circuits thus use increasingly more power than heretofore. This increases the amount of heat which must be transferred away from the semiconductor devices in order to prevent the devices, circuits and modules from becoming destroyed due to exposure to excessive heat. Thus, in most cases, a heat sink is desirable to dissipate heat from the semiconductor devices and circuits.

On the other hand, demand for miniaturization is the primary catalyst driving the usage of advanced packages such as chip scale packages (CSP) and flip chips. Both of them greatly reduce the amount of board real estate required when compared to the alternative ball grid array (BGA) and quad flat pack (QFP). Typically, a CSP is 20 percent larger than the die itself, while the flip chip has been described as the ultimate package precisely because it has no package.

A conventional flip chip package provided with a heat sink is shown in FIG. 1. The flip chip package comprises a substrate 100, an IC chip 102 mounted to the substrate 100, a stiffener ring 103 provided on the substrate 100 at a location adjacent to the IC chip 102 and a heat sink 106 disposed on the IC chip 102 and the stiffener ring 103. The method for manufacturing the flip chip package will now be described with reference to FIGS. 2a to 2c. At first, as shown in FIG. 2a, an IC chip 102 is attached to a substrate 100 by means of solder bumps 104 directly attached to the IC chip 102. Then, as shown in FIG. 2b, the IC chip is underfilled with a thermoset material 105. The underfill material 105 is then cured by heating to a predetermined temperature. Thereafter, as shown in FIG. 2c, a heat sink 106 is attached to the IC chip 102 and the stiffener ring 103 via an attach epoxy 108. The attach epoxy 108 also needs to be cured by another heating step. However, the time required to conduct the two separate curing steps increases the overall processing time thereby decreasing the throughput of the prior art flip chip package.

Additionally, the IC chip is formed of microcrystalline silicon and the heat sink is typically made of metal material. Since there is a significant difference between the IC chip and the heat sink in CTE (coefficient thermal expansion), the IC chip and the heat sink expand and contract in different amounts along with temperature fluctuations during the manufacturing processes. This causes warpage of the IC chip and the heat sink, which can induce malfunction of the IC chip. The warpage could also produce piezoelectric effects in sensitive devices. In some cases, the thermal stress due to CTE mismatch may result in chip cracking.

Accordingly, there exists a need in the art for a flip chip assembly and a method to make the same which overcomes, or at least reduces the above-mentioned problems of the prior art.

### SUMMARY OF THE INVENTION

It is an objective of the present invention to provide a simplified method which can be used to produce a flip chip package having a heat sink directly disposed thereon.

It's another object of the present invention to provide a method for producing a flip chip package which is capable of overcoming or at least reducing the problems of package warpage caused by CTE mismatch between the IC chip and the heat sink.

To achieve the above listed and other objects, the present invention provides a flip chip assembly comprises an IC chip having a plurality first solder bumps formed on a lower surface thereof and a heat sink having a plurality of second solder bumps, wherein the heat sink are attached to an upper surface of the IC chip via the second solder bumps. Preferably, an underfill is formed between the IC chip and the heat sink. The heat sink may be made of thermal conductive material such as aluminum. It is preferred that the heat sink is a dummy chip made from materials with a CTE matching the CTE of the IC chip. Wiring is not required for the dummy chip because it is not employed in the device operation. Preferably, the IC chip has a plurality of pads each made of under bump metallurgy (UBM) on an upper surface thereof. The second solder bumps of the heat sink are aligned with the pads of the IC chip.

The present invention further provides a method for-producing the flip chip assembly. The method comprises the steps as described below. First, a heat sink with a plurality of solder bumps is placed on an upper surface of an IC chip with a plurality solder bumps formed on a lower surface thereof. Then, the solder bumps of the heat sink are reflowed so as to securely attach the heat sink to the IC chip. Alternatively, the method may further include the steps of forming an underfill between the IC chip and the heat sink and curing the underfill. Furthermore, to increase the adhesion between the solder bumps of the heat sink and the IC chip, a plurality of pads each made of under bump metallurgy (UBM) are formed on the upper surface of the IC chip.

The present invention also provides a method of forming a flip chip package attached on a substrate. First, a IC chip is placed on the substrate such the solder bumps provided on the lower surface of the IC chip are aligned with contact pads provided on the substrate. Then, a heat sink with solder bumps is placed on the IC chip. In this embodiment, the solder bumps of the heat sink and the IC chip are reflowed at the same time to securely attach the IC chip to the substrate and securely attach the heat sink to the IC chip. Alternatively, the method may further include steps of forming an underfill between the IC chip and the heat sink as well as between the IC chip and the substrate, and curing the underfill in one step.

According to the present invention, a simplified method for producing a flip chip package is provided. The method is characterized in that the heat sink is attached to the IC chip by solder bumps such that the attachment between the IC chip and the heat sink as well as between the IC chip and the substrate can be accomplished in the same reflowing step. This significantly reduces the cycle time for the method illustrated in the present invention thereby cutting down the production cost. Furthermore, if a dummy chip with a CTE matching the CTE of the IC chip is used as the heat sink, the IC chip and the dummy chip expand and contract in substantially the same amount along with temperature fluctuations. Therefore, the problems of package warpage caused by CTE mismatch between the IC chip and the heat sink can be overcome or at least reduced by utilizing a dummy chip as the heat sink.

### BRIEF DESCRIPTION OF THE DRAWINGS

Other objects, advantages, and novel features of the invention will become more apparent from the following detailed description when taken in conjunction with the accompanying drawings.

FIG. 1 is a cross sectional view of a conventional flip chip package;

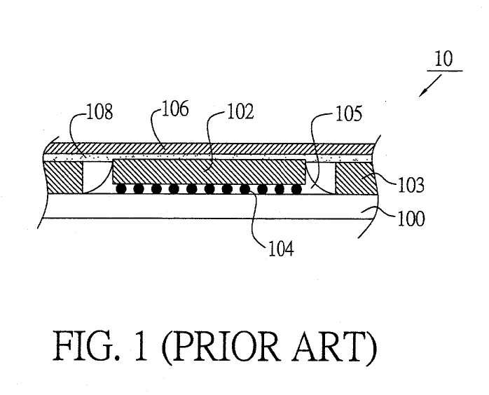

FIGS. 2a to 2c illustrate, in cross-sectional view, the major steps in a process of making the package of FIG. 1;

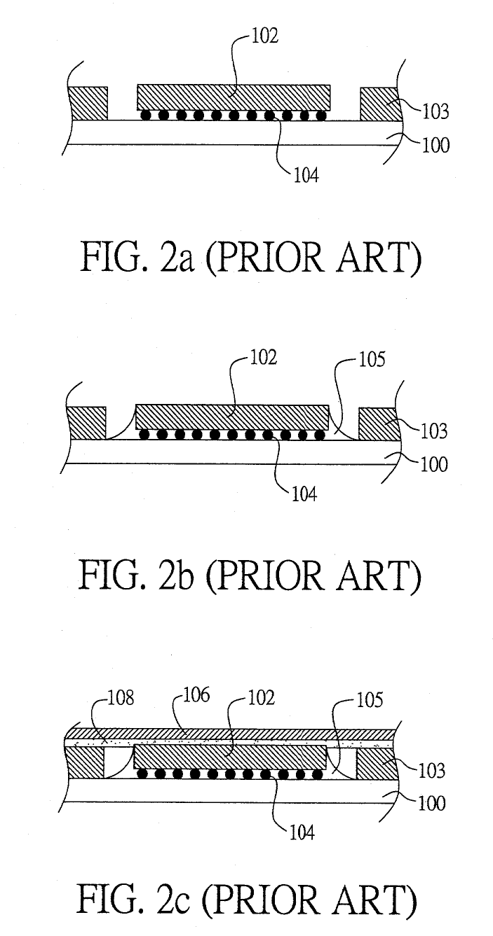

FIG. 3 is a cross sectional view of a flip chip assembly according to one embodiment of the present invention; and

FIGS. 4a to 4c illustrate, in cross-sectional view, the major steps in a method of forming a flip chip package attached on a substrate.

### DETAILED DESCRIPTION OF THE PREFERRED EMBODIMENT

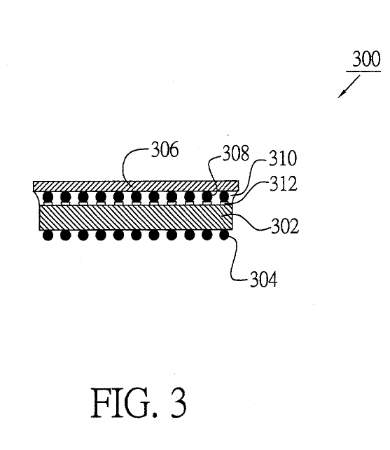

FIG. 3 illustrates a flip chip assembly 300 according to one embodiment of the present invention. The flip chip assembly includes an IC chip 302 having a plurality solder bumps 304 formed on a lower surface thereof and a heat sink 306 having a plurality of solder bumps 308, wherein the heat sink 306 are attached to an upper surface of the IC chip 302 via the solder bumps 308.

An underfill 310 is formed between the IC chip 302 and the heat sink 306 for sealing the gap between the solder bumps 308. The underfill ensures minimum load on the solder bumps 308 and becomes the primary load bearing member between the chip 302 and the heat sink 306 during thermal or power cycling induced due to the operation of the chip 302. Thermoset type materials are commonly used in the industry as underfill material. The heat sink may be made of thermal conductive material such as aluminum. It is preferred that the heat sink is a dummy chip made from materials with a CTE matching the CTE of the IC chip. Wiring is not required for the dummy chip because it is not employed in the device operation. Preferably, the IC chip 302 has a plurality of pads 312 each made of under bump metallurgy (UBM) on an upper surface thereof. The solder bumps 308 of the heat sink 306 are aligned with the pads 312 of the IC chip 302.

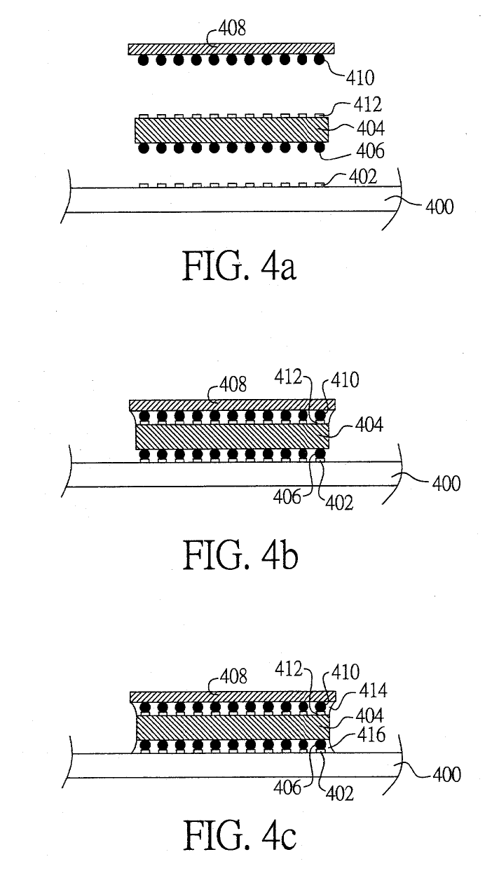

The method for forming a flip chip package attached on a substrate according to the present invention will now be described with reference to FIGS. 4a-4c. As shown in FIG. 4a, the substrate 400 is provided with a plurality of contact pads 402 adapted for electrical coupling to a IC chip 404. The substrate 400 may be a printed circuit board formed by conventional method or any of a number of build-up technologies. Alternatively, the substrate 400 may be a multi-layer ceramic substrate.

The IC chip 404 has a having a plurality solder bumps 406 formed on the lower surface thereof. Specifically, the solder bumps 406 may be formed by a conventional C4 (Controlled Collapse Chip Connection) process comprising the steps of: (a) forming an under bump metallurgy (UBM) (not shown) on bonding pads provided on the chip 404, and (b) forming solder bumps on the UBM by, e.g., vapor deposition, electroplating or printing. The heat sink 408 also has a plurality of solder bumps 410 formed thereon. The solder bumps 410 may be formed by screen printing of eutectic solder paste onto the heat sink 408 in a desired pattern. To increase the adhesion between the solder bumps 410 of the heat sink and the IC chip 404, a plurality of pads 412 each made of under bump metallurgy (UBM) are formed on the upper surface of the IC chip 404 in a pattern matching the pattern of the solder bumps 410.

The UBM of the pads 412 may include (a) adhesion layer (formed of Al or Cr) for providing a good adhesion to IC chip 404 and (b) wetting layer (formed of Ni, Cu, Mo or Pt) for providing a higher wetting power to solder thereby allowing for proper wetting of solder during solder-reflow process.

Referring to FIG. 4b, an automatic pick and place machine picks the chip 404 and accurately places the chip 404 to the predetermined area of the substrate 400 such that the solder bumps 406 of the IC chip 404 are accurately aligned with corresponding contact pads 402 of the substrate 400. The heat sink 408 is placed on the IC chip 404 by the same way such that the solder bumps 410 of the heat sink 408 are accurately aligned with corresponding pads 412 of the IC chip 404. The method of the present invention is characterized in that the solder bumps 406 and 410 are reflowed at the same time to securely attach the IC chip 404 to the substrate 400 as well as securely attach the heat sink 408 to the IC chip 404.

Alternatively, as shown in FIG. 4c, the method may further comprise steps of forming an underfill 414 between the IC chip 404 and the heat sink 408 as well as between the IC chip 404 and the substrate 400. It is noted that the underfill 414 forming step is optional in practicing the present invention. The underfill 414 and 416 is cured by heating to an appropriate temperature. The heating process can be accomplished by placing the assembly in an oven, placing the assembly on a heating plate, using heat generating lights, or blowing hot air on the underfill material, and heating to the appropriate temperature.

One advantage of the method according to the present invention is that the heat sink is attached with the IC chip by solder bumps such that the attachment between the IC chip and the heat sink as well as between the IC chip and the substrate can be accomplished in the same reflowing step. This significantly reduces the cycle time for the method illustrated in the present invention thereby cutting down the production cost. Furthermore, if a dummy chip with a CTE matching the CTE of the IC chip is used as the heat sink, the IC chip and the dummy chip expand and contract in substantially the same amount along with temperature fluctuations. Therefore, the problems of package warpage caused by CTE mismatch between the IC chip and the heat sink can be overcome or at least reduced by utilizing a dummy chip as the heat sink.

Although the invention has been explained in relation to its preferred embodiment, it is to be understood that many other possible modifications and variations can be made without departing from the spirit and scope of the invention as hereinafter claimed.

What is claimed is:

1. A flip chip assembly comprising:
an IC chip having a plurality of first solder bumps formed on a lower surface thereof; and
a heat sink having a plurality of second solder bumps,
wherein the heat sink are attached to an upper surface of the IC chip via the second solder bumps.

2. The assembly as claimed in claim 1, wherein the heat sink is made of metal.

3. The assembly as claimed in claim 1, wherein the heat sink is a dummy chip without wiring formed therein.

4. The assembly as claimed in claim 1, wherein the IC chip has a plurality of pads each made of under bump metallurgy (UBM) on the upper surface thereof, and the second solder bumps of the heat sink are aligned with the pads of the IC chip.

5. The assembly as claimed in claim 1, further comprising an underfill formed between the IC chip and the heat sink.

6. A method for producing a flip chip assembly comprising the following steps:
providing an IC chip having a plurality of first solder bumps formed on a lower surface thereof;
providing a heat sink having a plurality of second solder bumps formed thereon;
placing the heat sink on the IC chip; and
reflowing the second solder bumps so as to attach the heat sink to the IC chip.

7. The method as claimed in claim 6, wherein the IC chip has a plurality of pads each made of under bump metallurgy (UBM) on an upper surface thereof, and the placing step includes aligning the second solder bumps of the heat sink with the pads of the IC chip.

8. The method as claimed in claim 6, further comprising the steps of:
forming an underfill between the IC chip and the heat sink; and
curing the underfill.

9. The method as claimed in claim 6, wherein the heat sink is made of metal.

10. The method as claimed in claim 6, wherein the heat sink is a dummy chip without wiring formed therein.

11. A method of forming a flip chip package attached on a substrate provided with a plurality of contact pads, the method comprising the following steps:
providing an IC chip having a plurality of first solder bumps on a lower surface thereof;
providing a heat sink having a plurality of second solder bumps formed thereon;
placing the IC chip on the substrate such that the first solder bumps of the IC chip is aligned with the contact pads of the substrate;
placing the heat sink on the IC chip; and
reflowing the first and second solder bumps so as to securely attach the IC chip to the substrate and securely attach the heat sink to the IC chip at the same time.

12. The method as claimed in claim 11, wherein the IC chip has a plurality of pads each made of under bump metallurgy (UBM) on an upper surface thereof, and the heat sink placing step includes aligning the second solder bumps of the heat sink with the pads of the IC chip.

13. The method as claimed in claim 11 further comprising the steps of:
forming an underfill between the IC chip and the heat sink and between the IC chip and the substrate respectively; and
curing the underfill.

14. The method as claimed in claim 11, wherein the heat sink is made of metal.

15. The method as claimed in claim 11, wherein the heat sink is a dummy chip without wiring formed therein.
